(19) United States
(12) Patent Application Publication
(10) Pub. No.: US 2017/0338386 A1
(43) Pub. Date: Nov. 23, 2017

(54) FABRICATION METHOD FOR CASTING GRAPHENE QUANTUM DOTS ON LIGHT-EMITTING DIODES AND STRUCTURE THEREOF

(71) Applicant: CHUNG YUAN CHRISTIAN UNIVERSITY, Taoyuan City (TW)

(72) Inventors: JI-LIN SHEN, TAOYUAN CITY (TW); TZU-NENG LIN, TAOYUAN CITY (TW)

(21) Appl. No.: 15/237,823

(22) Filed: Aug. 16, 2016

(30) Foreign Application Priority Data
May 19, 2016 (TW) 105115439

(51) Int. Cl. H01L 33/50; H01L 33/32

(52) U.S. Cl. CPC H01L 33/502; H01L 33/32; H01L 2933/0041

(57) ABSTRACT

The present invention provides a fabrication method for casting graphene quantum dots on LEDs and the structure thereof. A graphene and an ethanol are mixed uniformly. After the laser ablation, centrifugal purification, and molecular filtration processes, a graphene quantum dots solution is produced. Afterwards, the graphene quantum dots solution is dripped on a light-emitting surface of an LED using a drop casting method. After the ethanol evaporates by standing still, a graphene-quantum-dot-cast layer is formed. The photocarriers in the graphene-quantum-dot-cast layer generated by the illumination of the LED can flow to the light-emitting surface of the LED and thus increasing the carrier concentration and the light-emitting quantum efficiency of the LED. Thereby, enhancing the fluorescent efficiency of the LED.

### FIELD OF THE INVENTION

The present innovation relates generally to a fabrication method for casting graphene quantum dots on light-emitting diodes (LEDs) and the structure thereof, and particularly to a fabrication method for nitride semiconductor LEDs having graphene quantum dots on their light-emitting surfaces and the structure thereof.

### BACKGROUND OF THE INVENTION

LEDs are made of semiconductors, which are solid-state materials with conduction capacity falling between conductors and insulators. Semiconductor material are formed from a single element as well as from a compound having two or more elements. Likewise, an alloy can also be used as a source for semiconductor material fabrication. Thereby, semiconductor materials can be categorized into element semiconductors, compound semiconductors, and metal-oxide semiconductors.

Take compound-semiconductor LEDs for example. Nitride semiconductors, such as aluminum nitride (AlN), gallium nitride (GaN), or indium nitride (InN), are direct-bandgap materials, which have low loss in momentum and thermal energy and high efficiency in optoelectric conversion. In addition, the light-emitting range of nitride semiconductors is broad, ranging from the ultraviolet to the visible light spectrum. Hence, they are suitable for fabricating light emitting electronic devices having wavelengths ranging from the green light to the ultraviolet light. The LEDs made by nitride semiconductors possesses advantages such as small size, low power consumption, low thermal dissipation (luminescence with low thermal radiation), long lifetime (reaching 100 thousand hours under the normal safe operating environment), and fast response (suitable for high-frequency operations). The applications are extensive and include industries of lighting, optoelectric displays, wireless communications, satellite positioning, and domestic appliances. Accordingly, once the light-emitting efficiency of nitride semiconductor LEDs are improved, the contribution to industrial applications will be huge.

In general, a new technology will stimulate the developments of the corresponding equipment and devices for meeting the new demands in production efficiency. To satisfy the requirements in the rapid evolution and diverse development of the optoelectric industry, many novel materials with practical values are continually being developed. In order to enhance the fluorescent efficiency of nitride semiconductor LEDs and thereby increase their industrial utility, a two-dimensional novel material, graphene, have been stressed and applied substantially.

Graphene is a planar thin film formed by sp² hybrid orbitals of carbon atoms in hexagonal honeycomb lattice. It is a two-dimensional material with the thickness of a single carbon atom. Since the discovery of the material by the research group formed by British scientists in 2004, the preparation of graphene and integration with various fields are started. The extensive applications of graphene also include the integration with the electronic devices formed by compound semiconductors. The outstanding chemical, thermal, electrical, and mechanical properties of graphene have created a new research direction for optoelectric devices. Graphene can instigate superior fluorescent efficiency to the compound semiconductor LEDs according to the prior research

Moreover, graphene quantum dots are nanometer particles formed by graphene, having lateral diameters less than tens of nanometers having different functional groups on the surface and the side for modifying. They exhibit apparent quantum confinement effect and edge effect, which lead to discontinuous energy levels, thus, emitting fluorescent light. Graphene quantum dots own the advantages of excellent chemical stability and biological compatibility, low toxicity, low cost, and resistance to photobleaching, enabling them with unlimited potentiality in biomedical sensing, cellular imaging, and optoelectric devices.

### SUMMARY

An objective of the present invention is to provide a fabrication method for casting graphene quantum dots on LEDs and the structure thereof. By using laser ablation, centrifugal purification, and molecular filtration processes, a graphene quantum dots solution can be prepared from the mixed liquid of graphene and ethanol.

Another objective of the present invention is to provide a fabrication method for casting graphene quantum dots on LEDs and the structure thereof. The graphene quantum dots solution is dripped on the light-emitting surface of an LED using a drop casting method. After the ethanol evaporates by standing still, a graphene-quantum-dot-cast layer is formed. By taking advantage of the work function difference between the graphene-quantum-dot-cast layer and the surface layer of the LED, the photocarriers in the graphene-quantum-dot-cast layer generated by the illumination of the LED can flow to the light-emitting surface of the LED, thus, increasing the carrier concentration and the light-emitting quantum efficiency of the LED. Thereby, enhancing the fluorescent efficiency of the LED.

A further objective of the present invention is to provide a fabrication method for casting graphene quantum dots on LEDs and the structure thereof. The preparation method for casting graphene quantum dots on the light-emitting surface of LEDs has the advantages of simplicity, low cost, and no pollution.

In order to achieve the above objectives and efficacies, the present invention provides a fabrication method for casting graphene quantum dots on LEDs and the structure thereof. According to the method, a graphene and an ethanol are to be mixed uniformly. Following, the mixture solution is placed on a rotating platform with a spinning rate of 80 rpm and concurrently illuminated by laser ablation for 5 minutes. The mixture is subsequently purified through centrifugation with a spinning rate of 6000 rpm. Afterwards, a molecular filter with a hole diameter of 0.22 μm is therefore used giving a solution having 3.5 nm graphene quantum dots. Finally, the graphene quantum dots solution is cast on the light-emitting surface of an LED. By standing still for a few minutes, the ethanol is evaporated forming a graphene-quantum-dot-cast layer. The work function of the graphene-quantum-dot-cast layer is smaller than that of the light-emitting surface of the LED. Thereby, the photocarriers in the graphene-quantum-dot-cast layer generated by the illumination of the LED can flow to the light-emitting surface of the LED increasing the carrier concentration and the light-emitting quantum efficiency of the LED. Accordingly, enhancing the fluorescent efficiency of the LED.

### BRIEF DESCRIPTION OF THE DRAWINGS

FIG. 1 shows a flowchart of the fabrication method for casting graphene quantum dots on LEDs according to the present invention;

FIG. 2 shows a schematic diagram of the graphene-quantum-dot-cast layer and the LED according to the first embodiment of the present invention;

FIG. 3 shows a schematic diagram of the graphene-quantum-dot-cast layer and the LED according to the second embodiment of the present invention;

FIG. 4 shows a picture of graphene quantum dots according to the present invention; and

FIG. 5 shows luminescence intensity versus current curves of nitride semiconductor LEDs according to the present invention.

### DETAILED DESCRIPTION

In order to make the structure and characteristics as well as the effectiveness of the present invention to be further understood and recognized, the detailed description of the present invention is provided as follows along with embodiments and accompanying figures.

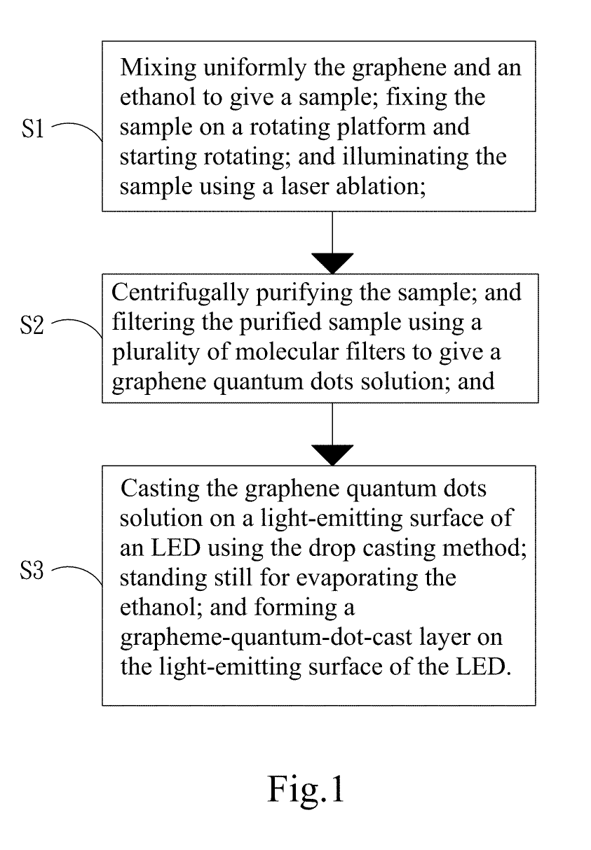

Please refer to FIG. 1, which shows a flowchart of the fabrication method for casting graphene quantum dots on LEDs according to the present invention. As shown in the figure, the fabrication method for casting graphene quantum dots on LEDs according to the present invention comprises the following steps:
Step S1: Mixing uniformly a graphene and an ethanol to give a sample; fixing the sample on a rotating platform and starting rotating; and illuminating the sample using a laser ablation;
Step S2: Centrifugally purifying the sample; and filtering the purified sample using a plurality of molecular filters to give a graphene quantum dots solution; and
Step S3: Casting the graphene quantum dots solution on a light-emitting surface of an LED using the drop casting method; standing still for evaporating the ethanol; and forming a graphene-quantum-dot-cast layer on the light-emitting surface of the LED.

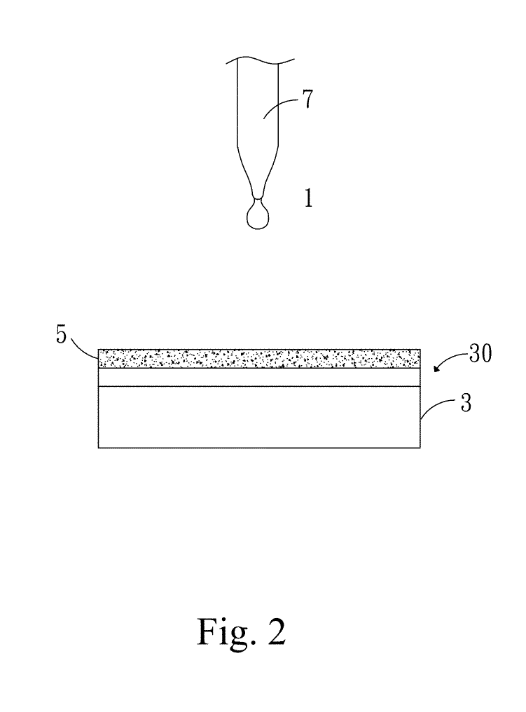

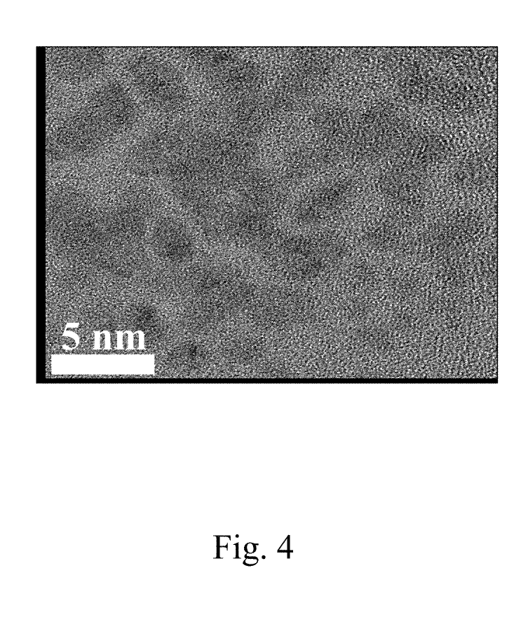

Please refer to FIG. 2 and FIG. 4, which show a schematic diagram of the graphene-quantum-dot-cast layer and the LED according to the first embodiment of the present invention and a picture of graphene quantum dots according to the present invention. A graphene and an ethanol are mixed uniformly according to the present invention. Take 600 microliters of the mixed solution and fix it on a rotating platform (not shown in the figures). The spinning rate of the rotating platform is set to 80 rpm. The laser ablation adopts an optical parametric oscillator pulsed laser with a wavelength of 415 nm and the energy of 48 mJ illuminating on the graphene and ethanol for 5 minutes. Subsequently, the solution is centrifugally purified using a centrifuge (not shown in the figure) spinning at 6000 rpm and filtered using a molecular filter with a hole diameter of 0.22 μm to give a graphene-quantum-dot solution 1 (as shown in FIG. 2). As shown in FIG. 4, by referring to the scale of 5 nm in a transmission electron microscope, it can be observed that the size of the graphene quantum dots is approximately 3.5 nm.

Next, the graphene-quantum-dots solution 1 is integrated on the light-emitting surface 30 of an LED 3 using the drop casting method. Stand the solution still for 5 minutes for evaporating the ethanol. A graphene-quantum-dot-cast layer 5 is formed on the light-emitting surface 30 of the LED 3. In the drop casting method, a pipette 7 is used for sipping approximately 5 microliters of graphene-quantum-dot solution 1 to cast on the light-emitting surface 30 of the LED 3. The LED 3 can be a nitride semiconductor LED.

Owing to the difference in the work functions of the graphene-quantum-dot-cast layer 5 and the surface material of the LED 3, as the LED 3 containing the graphene-quantum-dot-cast layer 5 emits light, the photocarriers generated by illuminating the graphene-quantum-dot-cast layer 5 will flow to the light-emitting surface 30 of the LED 3. Thus, enhancing the light emitting efficiency of the LED 3. Increasing the carrier concentration and the light-emitting quantum efficiency of the LED 3.

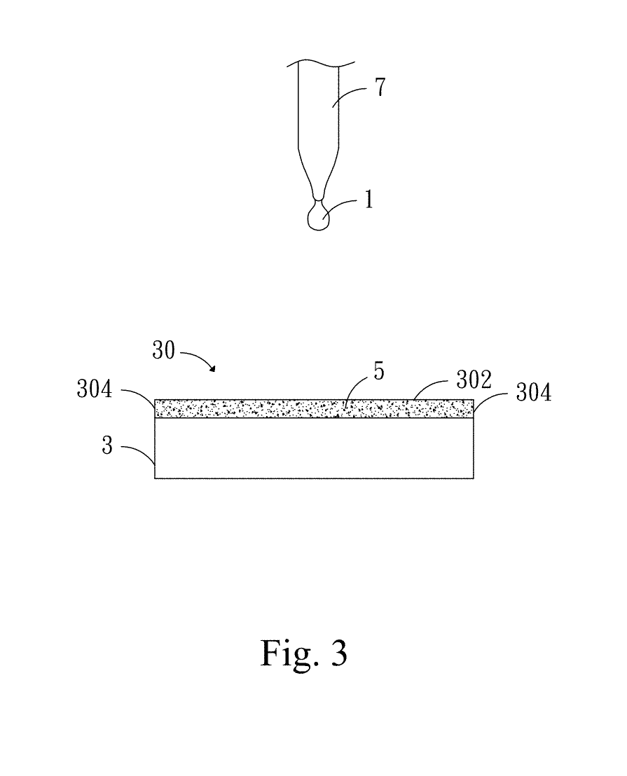

Please refer to FIG. 3, which shows a schematic diagram of the graphene-quantum-dot-cast layer and the LED according to the second embodiment of the present invention. As shown in the figure, the light-emitting surface 30 of the LED 3 according to the second embodiment of the present invention includes a top light-emitting surface 302 and a side light-emitting surface 304. In the second embodiment, the same fabrication and casting methods for graphene quantum dots as in the first embodiment are adopted on the light-emitting surface of the LED 3. In the first embodiment, the fabrication and casting methods have been described. Hence, they will not be described again here. It is noticeable that the graphene-quantum-dot-cast layers 5 are cast on both the top light-emitting surface 302 and the side light-emitting surface 304 of the LED 3 according to the second embodiment of the present invention. Thereby, when the LED 3 containing graphene quantum dots emit light from the top or side light-emitting surface 302, 304, the photocarriers generated by illuminating the graphene-quantum-dot-cast layer 5 will flow to the light-emitting surface 30, namely, the top and side light-emitting surfaces 302, 304, of the LED 3. Thus, increasing the carrier concentration and light-emitting quantum efficiency of LED 3. Consequently, enhancing the light emitting efficiency of LED 3. In addition, LEDs also include flip-chip LEDs. Moreover, the light emitted from the quantum wells of LEDs includes visible and invisible light.

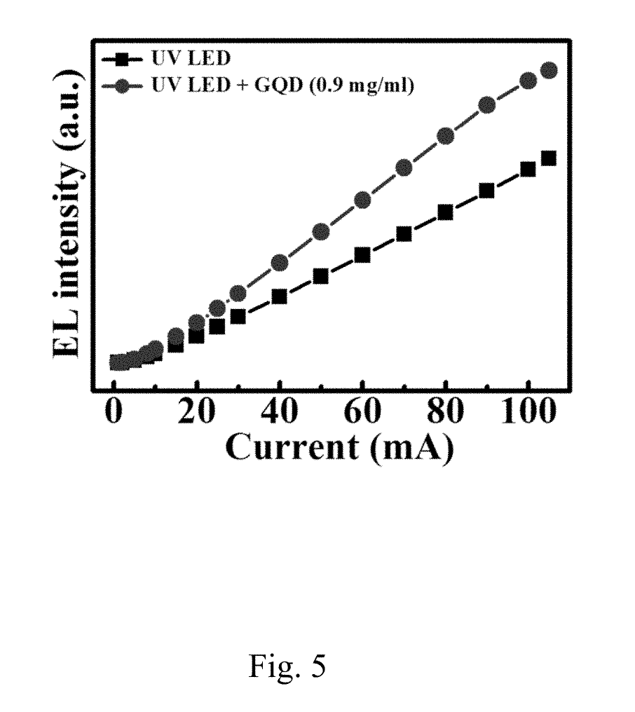

Please refer to FIG. 5, which shows luminescence intensity versus current curves of nitride semiconductor LEDs according to the present invention. As shown in the figure, by measuring the luminescence intensity at different currents, the luminescence intensities of nitride semiconductor LEDs with graphene quantum dots are tested. By applying an identical external current, the luminescence intensities of nitride semiconductor LEDs with and without graphene quantum dots are compared. It is found that the luminescence intensity of nitride semiconductor LEDs with graphene quantum dots (the curve by linking circles in FIG. 5) increased by approximately 20% compared to the luminescence intensity of nitride semiconductor LEDs without graphene quantum dots (the curve by linking squares in FIG. 5).

In order to improve the light-emitting efficiency of the nitride semiconductor LEDs, according to the present invention, the process of casting graphene quantum dots is utilized onto the light-emitting surfaces of the nitride semiconductor LEDs. The fabricated graphene quantum dots are non-toxic carbon-base materials having a simple preparation method and low costs. Thereby, no pollution is present from the starting material up to the synthesis process and until the final product/s. To sum up, the present invention provides a fabrication method for graphene quantum dots. By casting the graphene quantum dots on the light-emitting surfaces of nitride semiconductor LEDs, their light-emitting efficiency will be enhanced. The preparation method for graphene quantum dots is simple, rapid, and low-cost. In addition, graphene quantum dots are carbon-based materials without pollution. As they are cast on the light-emitting surfaces of nitride semiconductor LEDs, the nitride semiconductor LEDs will own the both advantages of the graphene and nitride semiconductor LEDs. Consequently, the light-emitting efficiency of nitride semiconductor LEDs will be improved.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

What is claimed is:

1. A fabrication method for casting graphene quantum dots on light-emitting diodes, comprising steps of:
mixing uniformly a graphene and an ethanol to give a sample; fixing the sample on a rotating platform and starting rotating; and illuminating the sample using a laser ablation;
centrifugally purifying the sample; and filtering the purified sample using a plurality of molecular filters to give a graphene quantum dots solution; and
casting the graphene quantum dots solution on a light-emitting surface of a light-emitting diode using a drop casting method; standing still for evaporating the ethanol; and forming a graphene-quantum-dot-cast layer on the light-emitting surface of the light-emitting diode.

2. The fabrication method for casting graphene quantum dots on light-emitting diodes of claim 1, wherein the laser ablation adopts an optical parametric oscillator pulsed laser with a wavelength of 415 nm and the energy of 48 mJ illuminating on the graphene and the ethanol for 5 minutes.

3. The fabrication method for casting graphene quantum dots on light-emitting diodes of claim 2, wherein the graphene and the ethanol are placed on the rotating platform with a spinning rate of 80 rpm and illuminated for 5 minutes by pulsed laser.

4. The fabrication method for casting graphene quantum dots on light-emitting diodes of claim 1, wherein the spinning rate is 6000 rpm in the step of centrifugal purification.

5. The fabrication method for casting graphene quantum dots on light-emitting diodes of claim 1, wherein the hole diameter of the plurality molecular filters is 0.22 μm.

6. The fabrication method for casting graphene quantum dots on light-emitting diodes of claim 1, wherein the size of the graphene quantum dots is 3.5 nm.

7. The fabrication method for casting graphene quantum dots on light-emitting diodes of claim 1, wherein the light-emitting diode is a nitride semiconductor light-emitting diode.

8. A structure of light-emitting diode having graphene quantum dots, wherein a light-emitting surface of a light-emitting diode include a graphene-quantum-dot-cast layer.

9. The structure of light-emitting diode having graphene quantum dots of claim 8, wherein the light-emitting diode is a nitride semiconductor light-emitting diode.

10. The structure of light-emitting diode having graphene quantum dots of claim 8, wherein the size of the graphene quantum dots is 3.5 nm.
